(19) United States
(12) Patent Application Publication
(10) Pub. No.: US 2024/0204026 A1
(43) Pub. Date: Jun. 20, 2024

(54) IMAGE SENSOR PACKAGE AND METHOD FOR MANUFACTURING THE SAME

(71) Applicant: Samsung Electronics Co., Ltd., Suwon-si (KR)

(72) Inventors: JUNGHOON KANG, Suwon-si (KR); UN-BYOUNG KANG, Suwon-si (KR); SEUNGWAN SHIN, Suwon-si (KR); JUNG HYUN LEE, Suwon-si (KR)

(21) Appl. No.: 18/223,307

(22) Filed: Jul. 18, 2023

(30) Foreign Application Priority Data
Dec. 14, 2022 (KR) 10-2022-0174876

(51) Int. Cl. H01L 27/146

(52) U.S. Cl. CPC H01L 27/14634; H01L 27/14618; H01L 27/14623; H01L 27/14636

(57) ABSTRACT

An image sensor package according to an embodiment includes: a substrate including a metal portion; an image sensor chip on the substrate; and a transparent glass cover disposed on the substrate and including an upper plate and sidewalls, the upper plate and the sidewalls defined by a cavity at a lower portion and spaced from the image sensor chip, wherein the sidewalls are directly bonded to the metal portion of the substrate, and the image sensor chip is sealed by the transparent glass cover and the substrate.

### CROSS-REFERENCE TO RELATED APPLICATION

This application claims priority under 35 U.S.C. § 119 to and the benefit of Korean Patent Application No. 10-2022-0174876 filed in the Korean Intellectual Property Office on Dec. 14, 2022, the entire contents of which are incorporated herein by reference.

### BACKGROUND OF THE DISCLOSURE

### (a) Field of the Disclosure

The present disclosure relates to an image sensor package and a manufacturing method thereof.

### (b) Description of the Related Art

An image sensor chip is an electronic part for sensing intensities and colors of optical images, converting them into digital image data, and storing, transmitting, and reproducing images. The image sensor chip is a key component of a smartphone camera and a digital camera.

The image sensor chip is mounted on a device in an image sensor package form to protect the image sensor chip, prevent foreign materials from permeating into an image sensing region of the image sensor chip, and supply power and output signals to the image sensor chip and the substrate.

A conventional image sensor package has a hermetic structure of mounting an image sensor chip on a substrate for coupling electrical signals to the outside, bonding wires on the substrate to transmit signals, and sealing the image sensor chip with a transparent glass cover and a support holder.

The conventional image sensor package bonds the transparent glass cover and the support holder to each other and bonds the support holder and the substrate to each other by using a resin, so a four component bonding including the transparent glass cover, the support holder, the substrate, and the resin is used in order to seal the image sensor chip.

However, when the image sensor chip is packaged by the four component bonding of the transparent glass cover, the support holder, the substrate, and the resin, thermal stress issues caused by different thermal characteristics of materials/components may occur. For example, the support holder and the substrate have different coefficients of thermal expansion so the resin on a portion disposed between the support holder and the substrate may be cracked.

Further, the bonding process using a resin is performed by a reflow process in a condition of a high-temperature aqueous vapor pressure of about 240 degrees Celsius. Because of the high temperature aqueous vapor pressure during the reflow process, aqueous vapors may permeate into the bonded portion in the bonding process using a resin, and the permeated aqueous vapors cause weak portions that are not easily bonded on the bonded portions of the resin and transparent glass cover, the resin and the support holder, and the resin and the substrate.

Further, when the bonding process is performed by using a resin, it is difficult to bond the transparent glass cover and the support holder on a same horizontal level. Therefore, according to the conventional image sensor package, to bond the transparent glass cover and the support holder to each other, the resin is provided above the support holder, and the transparent glass cover is provided above the resin. However, the above-noted method may increase the product size because it is performed after securing a sufficient bonding area.

Hence, it is needed to develop new image sensor package systems to address the drawbacks of the conventional image sensor packages.

### SUMMARY OF THE DISCLOSURE

The present disclosure has been made in an effort to provide an image sensor package for sealing an image sensor chip by a transparent glass cover and a substrate without a support holder and a resin by directly bonding a sidewall of a transparent glass cover and a metal portion of the substrate.

The present disclosure has been made in another effort to provide a method for manufacturing an image sensor package for directly bonding a metal portion of a substrate and a transparent glass cover according to a laser welding method so as to seal an image sensor chip.

An embodiment of the present disclosure provides an image sensor package including: a substrate including a metal portion; an image sensor chip on the substrate; and a transparent glass cover disposed on the substrate and including an upper plate and sidewalls, the upper plate and the sidewalls defined by a cavity at a lower portion and spaced from the image sensor chip, wherein the sidewalls are directly bonded to the metal portion of the substrate, and the image sensor chip is sealed by the transparent glass cover and the substrate.

The image sensor package may further include a light blocking film consecutively extending along surfaces of the sidewalls and along an edge of a surface of the upper plate.

The upper plate and the sidewalls may be integrated.

The metal portion may include a square ring shape surrounding the image sensor chip.

The metal portion may include stainless steel (SUS), copper (Cu), or aluminum (AI).

Another embodiment of the present disclosure provides an image sensor package including: a substrate including an insulation layer, redistribution lines and redistribution vias formed in the insulation layer, and a metal portion; an image sensor chip on the substrate; an connection member for electrically coupling the redistribution lines and the image sensor chip; a transparent glass cover disposed on the substrate and including an upper plate and sidewalls, the upper plate and the sidewalls defined by a cavity at a lower portion and spaced from the image sensor chip; a light blocking film consecutively extending along surfaces of the sidewalls and along an edge of a surface of the upper plate; and laser welding lines protruding from the metal portion, wherein the sidewalls are directly bonded to the metal portion by the laser welding lines, and the image sensor chip is sealed by the transparent glass cover and the substrate.

The metal portion may be electrically insulated from the image sensor chip and the redistribution lines.

An upper surface of the metal portion may protrude from an upper surface of the insulation layer.

An upper surface of the metal portion may have a same level as the upper surface of the insulation layer.

The image sensor package may include a fixing portion bonded to a bottom surface of the metal portion and embedded in the insulation layer.

The connection member may include a bonding wire.

The light blocking film may include a first region extending along an internal surface of the sidewalls, and a second region having a predetermined first width and extending toward a center of an internal surface of the upper plate from an edge of the internal surface of the upper plate.

The predetermined first width may be longer than a length from the edge of the internal surface of the upper plate to a point of the surface of the upper plate vertically overlapping an end point of a bonding pad to which the bonding wire is bonded.

Another embodiment of the present disclosure provides a method for manufacturing an image sensor package including: forming a substrate including an insulation layer, redistribution lines and redistribution vias formed in the insulation layer, and a metal portion; mounting an image sensor chip on the substrate; and directly bonding a transparent glass cover on the metal portion by laser welding to seal the image sensor chip.

In the directly bonding of a transparent glass cover onto the metal portion, laser welding lines in a first direction bonding the metal portion and the transparent glass cover to each other are formed on the metal portion.

In the directly bonding of a transparent glass cover onto the metal portion, laser welding lines in a second direction bonding the metal portion and the transparent glass cover to each other are formed on the metal portion, and the second direction may traverse the first direction.

In the laser welding, the laser has a pulse duration of 100 ns to 400 fs.

In the laser welding, the laser has a wavelength of 355 nm to 1064 nm.

The method may further include forming a transparent glass cover in which a cavity is formed by an etching, before the directly bonding of a transparent glass cover on the metal portion by laser welding to seal the image sensor chip.

The method may further include printing ink on the transparent glass cover.

According to the embodiment, the image sensor package sealing the image sensor chip by the transparent glass cover and the substrate without the support holder and the resin by directly bonding the sidewall of the transparent glass cover and the metal portion of the substrate to each other. By this, issues generated when the image sensor chip is sealed with multiple materials having different coefficients of thermal expansion may be addressed, the image sensor chip may be sealed with the integrated structure, and the size of the image sensor package may be reduced.

The embodiment may provide the method for manufacturing an image sensor package for directly bonding the metal portion of the substrate and the transparent glass cover according to the laser welding method so that the image sensor chip may be sealed. By this, the image sensor package for addressing issues including the high temperature aqueous vapor pressure risk by the use of a resin and the possibility of generation of cracks, having high heat resistance and high rigidity, and obtaining high-level results in the thermal cycle test (TC) may be manufactured.

The embodiment may provide the method for manufacturing an image sensor package for directly bonding two components/materials including the metal portion/pattern of the substrate and the transparent glass cover without the support holder and the resin. Hence, the bonding material may be reduced, and the process may be simplified.

### BRIEF DESCRIPTION OF THE DRAWINGS

FIG. 1 shows a perspective view of an image sensor package in which a metal portion of a substrate and a transparent glass cover having an integrated structure are directly bonded to each other to seal an image sensor chip, and a light blocking film is attached to a transparent glass cover according to an embodiment.

FIG. 2 shows a cross-sectional view of an image sensor package of FIG. 1 with respect to a cross-section along A-A according to an embodiment.

FIG. 3 shows a cross-sectional view of an image sensor package including a disposition of a metal portion according to an embodiment.

FIG. 4 shows a cross-sectional view of an image sensor package including a disposition of a metal portion according to an embodiment.

FIG. 5 shows a cross-sectional view of an image sensor package including a disposition of a light blocking film according to an embodiment.

FIG. 6 shows a top plan view an interface between a directly bonded transparent glass cover and a metal portion of a substrate according to an embodiment.

FIG. 7 shows an image of regions B and C in a top plan view on an interface between a directly bonded transparent glass cover and a metal portion of a substrate of FIG. 6 according to an embodiment.

FIG. 8 shows a cross-sectional view of providing a transparent glass cover in a method for manufacturing an image sensor package according to an embodiment.

FIG. 9 shows a cross-sectional view of providing a substrate in a method for manufacturing an image sensor package according to an embodiment.

FIG. 10 shows a cross-sectional view of mounting an image sensor chip on a substrate in a method for manufacturing an image sensor package according to an embodiment.

FIG. 11 shows a cross-sectional view of electrically coupling an image sensor chip and a substrate by use of a bonding wire in a method for manufacturing an image sensor package according to an embodiment.

FIG. 12 shows a cross-sectional view of disposing a transparent glass cover on a substrate in a method for manufacturing an image sensor package according to an embodiment.

FIG. 13 shows bonding a metal portion of a substrate and a transparent glass cover by laser welding in a method for manufacturing an image sensor package according to an embodiment.

FIG. 14 shows a cross-sectional view of an image sensor package in which a transparent glass cover which is integrated and a metal portion of a substrate seal an image sensor chip after laser welding according to an embodiment.

FIG. 15 shows a cross-sectional view of an image sensor package for sealing an image sensor chip mounted on a substrate by a flip chip bonding method with a transparent glass cover having an integrated structure and a metal portion of a substrate according to an embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

The size and thickness of each configuration shown in the drawings are arbitrarily shown for better understanding and ease of description, but the present disclosure is not limited thereto.

Throughout this specification and the claims that follow, when it is described that an element is “coupled” to another element, the element may be “directly coupled” to the other element or “indirectly coupled” to the other element through a third element. Unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Similarly, when an element is referred to as being “directly connected” or “directly coupled” to another element, or as “contacting” or “in contact with” another element, there are no intervening elements present at the point of contact. Other words used to describe the relationship between elements should be interpreted in a like fashion (e.g., “between” versus “directly between,” “adjacent” versus “directly adjacent,” etc.). The word “on” or “above” means positioned on or below the object portion, and does not necessarily mean positioned “on” or “above” the upper surface of the object portion based on a gravitational direction.

The phrase “on a plane” means viewing the object portion from the top, and the phrase “on a cross-section” means viewing a cross-section of which the object portion is vertically cut from the side.

An image sensor package and a method for manufacturing an image sensor package according to an embodiment will now be described with reference to accompanying drawings.

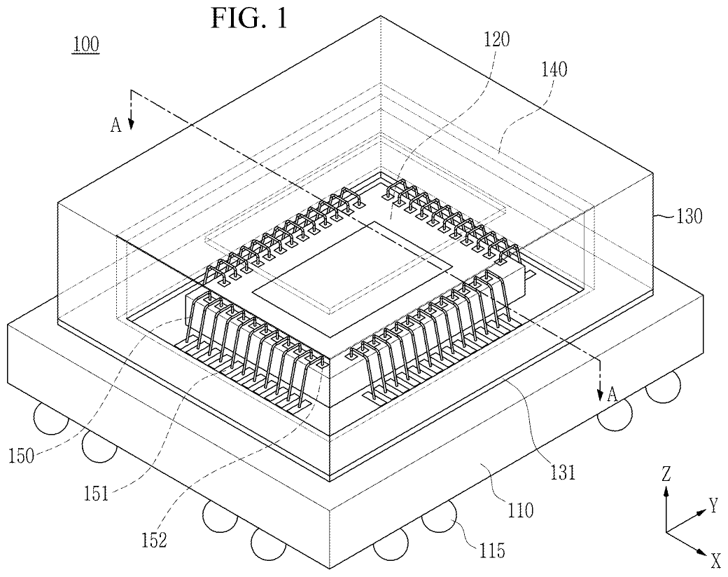

FIG. 1 shows a perspective view of an image sensor package 100 in which a metal portion 131 of a substrate 110 and a transparent glass cover 130 having an integrated structure are directly bonded to seal an image sensor chip 120, and a light blocking film 140 is attached to the transparent glass cover 130 according to an embodiment.

Referring to FIG. 1, the image sensor package 100 may include a substrate 110, an image sensor chip 120 mounted on the substrate 110, a transparent glass cover 130, a light blocking film 140, and a bonding wire 150. The image sensor chip 120 and the bonding wire 150 are sealed/encapsulated by the transparent glass cover 130 and the substrate 110. The transparent glass cover 130 covers an upper surface and lateral sides of the image sensor chip 120, and the substrate 110 covers a bottom surface of the image sensor chip 120. For example, the transparent glass cover 130 vertically overlaps the upper surface of the image sensor chip 120, and horizontally overlaps the lateral sides of the image sensor chip 120. For example, the substrate 110 vertically overlaps the bottom surface of the image sensor chip 120. The image sensor chip 120 is electrically coupled to the substrate 110 through the bonding wire 150.

As used herein, components described as being “electrically connected” or “electrically coupled” are configured such that an electrical signal can be transferred from one component to the other (although such electrical signal may be attenuated in strength as it transferred and may be selectively transferred).

Bottom surfaces of sidewalls of the transparent glass cover 130 and the metal portion 131 of the substrate 110 have square ring shapes in a plan view, are bonded to each other by a laser welding, thereby sealing/encapsulating the image sensor chip 120, e.g., within a space encapsulated by the transparent glass cover 130 and the substrate 110. The light blocking film 140 is attached to the transparent glass cover 130 so that no external light may be input to the location in which the bonding wire 150 is disposed, e.g., through the light blocking film 140. The light blocking film 140 is made of an opaque material, but FIG. 1 shows that the light blocking film 140 is transparent so as to display an internal configuration of the light blocking film 140. For example, the light blocking film 140 may be an opaque film.

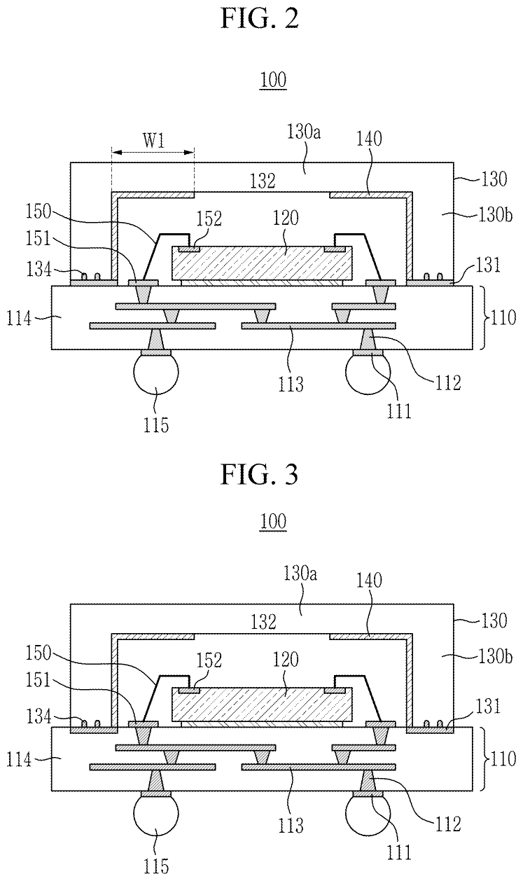

FIG. 2 shows a cross-sectional view of an image sensor package 100 of FIG. 1 with respect to a cross-section along A-A according to an embodiment.

Referring to FIG. 2, the image sensor package 100 may include a substrate 110, an image sensor chip 120, a transparent glass cover 130, a light blocking film 140, and bonding wires 150.

The substrate 110 may include a redistribution layer. The substrate may include a plurality of first bonding pads 111, a plurality of redistribution vias 112, a plurality of redistribution lines 113, an insulation layer 114, a plurality of second bonding pads 151, and a metal portion 131. In an embodiment, the substrate 110 may include or may be a printed circuit board (PCB), a ceramic leadless chip carrier (CLCC), and/or a plastic leaded chip carrier (PLCC).

The first bonding pads 111 are bonded to an external connection terminal 115 electrically coupled to an external device. The second bonding pads 151 are bonded to the bonding wire 150 electrically coupled to the image sensor chip 120.

In an embodiment, the first bonding pads 111 and the second bonding pads 151 may include or be formed of a copper layer. In an embodiment, the first bonding pads 111 and the second bonding pads 151 may include or be formed of a layered structure in which a nickel layer or a gold layer is made/formed on the copper layer. In an embodiment, the first bonding pads 111 and the second bonding pads 151 may include or be formed of at least one of: copper, aluminum, tungsten, nickel, gold, tin, titanium, and their alloys.

The redistribution vias 112 and the redistribution lines 113 are bonded to the first bonding pads 111 and the second bonding pads 151 and are thus electrically coupled to each other. In an embodiment, the redistribution vias 112 and the redistribution lines 113 may include or be formed of at least one of: copper, aluminum, tungsten, nickel, gold, tin, titanium, and their alloys.

The insulation layer 114 embeds the redistribution vias 112 and the redistribution lines 113. In an embodiment, the insulation layer 114 may be a molding compound, a molding underfill, an epoxy, and/or a resin.

A limited number of redistribution vias 112 and redistribution lines 113 are shown in an embodiment described with reference to FIGS. 2, 3, 4, 5, 9, 10, 11, 12, and 14, and the actual number of the redistribution vias 112 and the redistribution lines 113 are not limited thereto, and a greater number of the redistribution vias 112 and the redistribution lines 113 may be allowable.

The metal portion 131 is bonded to the transparent glass cover 130 by a laser welding. The metal portion 131 includes an upper surface and a bottom surface. The upper surface is bonded to a bottom surface of the sidewall of the transparent glass cover 130, and the bottom surface is bonded to the insulation layer 114 of the substrate 110.

In an embodiment, the metal portion 131 may have a square ring shape surrounding a lateral side of the image sensor chip 120. For example, the metal portion 131 is a metal pattern bonded to the bottom surface of the transparent glass cover 130 and enclosing the image sensor chip 120, e.g., in a plan view. In an embodiment, the metal portion 131 may include or be formed of stainless steel (SUS), copper (Cu), and aluminum (Al). In an embodiment, the metal portion 131 may be electrically insulated from the image sensor chip 120 and the redistribution lines 113 of the substrate 110.

The image sensor chip 120 is mounted on the substrate 110. The image sensor chip 120 mounted in the substrate 110 is electrically coupled to the redistribution lines 113 in the substrate 110 through the bonding wire 150. The image sensor chip 120 senses light input to a light transmitter 132 of the transparent glass cover 130 to which the light blocking film 140 is not attached. In an embodiment, the image sensor chip 120 may include or may be a CMOS image sensor (CIS). For example, the image sensor chip 120 may receive light coming through a light transmitting area 132 of the transparent glass cover 130 and may convert the received light into an electric signal.

The transparent glass cover 130 is disposed on the substrate 110. The transparent glass cover 130 includes an upper plate 130a and sidewalls 130b. In an embodiment, the upper plate 130a and the sidewalls 130b of the transparent glass cover 130 may be integrally formed. For example, the upper plate 130a and the sidewalls 130b of the transparent glass cover 130 may be formed as one body without boundaries between the upper plate 130a and the sidewalls 130b. The upper plate 130a of the transparent glass cover 130 is spaced from the upper surface of the image sensor chip 120. For example, there is a gap between the upper plate 130a of the transparent glass cover 130 and the top surface of the image sensor chip 120 in a vertical direction. The sidewalls 130b of the transparent glass cover 130 are spaced from the lateral sides of the image sensor chip 120. For example, there is a gap between each of the sidewalls 130b of the transparent glass cover 130 and a corresponding one of the lateral surfaces of the image sensor chip 120 in a horizontal direction. The upper plate 130a and the sidewalls 130b of the transparent glass cover 130 are defined by a lower cavity. For example, the upper plate 130a and the sidewalls 130b of the transparent glass cover 130 may form a cavity surrounded by the upper plate 130a and the sidewalls 130b. In an embodiment, a light filter (not shown) may be formed on a surface of the transparent glass cover 130. The light filter may transmit or block a specific wavelength range of light incident on the transparent glass cover 130.

In an embodiment, the transparent glass cover 130 may include a material for reducing reflectance of the incident light and increasing transmittance. In an embodiment, the transparent glass cover 130 may include an aluminosilicate.

The bottom surfaces of the sidewalls 130b of the transparent glass cover 130 are directly bonded to the upper surface of the metal portion 131. As the transparent glass cover 130 is directly bonded to the metal portion 131 without using an adhesive material, the issues generated when the image sensor chip is sealed with multiple materials having different heat characteristics may be addressed, the image sensor chip may be sealed as an integrated structure, the size of the image sensor package may be reduced, and the process condition may be simplified.

Laser welding lines 134 are lines generated by bonding the bottom surfaces of the sidewalls 130b of the transparent glass cover 130 and the upper surface of the metal portion 131 to each other, and is disposed between the bottom surfaces of the sidewalls 130b of the transparent glass cover 130 and the upper surface of the metal portion 131. For example, the laser welding lines 134 may be at a boundary between the sidewalls 130b of the transparent glass cover 130 and the metal portion (metal pattern) 131.

The light blocking film 140 is attached to the transparent glass cover 130. The light blocking film 140 blocks/prevents the light input/entering from the outside and being reflected by the bonding wire 150 thereby being input to (e.g., entering) the image sensor. When light is reflected from the bonding wire 150 and is input to (e.g., incident on) the image sensor, images detected by the image sensor may be deteriorated. For example, the deteriorations of images may be caused by a ghost image problem or a flare phenomenon that circular frames that are unreal, glare, and/or light points formed in the images.

In an embodiment, the light blocking film 140 may include or be formed of ink. In an embodiment, the light blocking film 140 is an ink composition and may include tricobalt tetroxide, magnetite black, copper·iron·manganese black, and titan black with a starting raw material such as carbon black, a copper·iron·manganese complex oxide, or a cobalt oxide. In another embodiment, the light blocking film 140 may include or may be a ready-made film and be attached to the transparent glass cover 130.

The light blocking film 140 may include a first region extending along an internal surface of the sidewalls 130b of the transparent glass cover 130 and a second region extending toward a center of the upper plate 130a from an edge of an internal surface of the upper plate 130a of the transparent glass cover 130. For example, the first region of the light blocking film 140 may be formed on the whole internal surface of the sidewalls 130b of the transparent glass cover 130, and the second region of the light blocking film 140 may be formed on a portion of an inner surface of the upper plate 130a of the transparent glass cover 130 and extend from a top end of the first region of the light blocking film 140 in a direction approaching the center of the inner surface of the upper plate 130a of the transparent glass cover 130. The second region of the light blocking film 140 may have a predetermined first width W1, e.g., from an outermost end of the second region of the light blocking film 140 meeting/contacting the top of the first region of the light blocking film 140 to an innermost end of the second region of the light blocking film 140. In an embodiment, the predetermined first width W1 of the second region of the light blocking film 140 may be longer than a length up to a crossing of a vertical direction of the location on which the bonding wire 150 is bonded to a plurality of third bonding pads 152 on the image sensor chip 120 and the internal surface of the upper plate 130a of the transparent glass cover 130 from the edge of the internal surface of the upper plate 130a of the transparent glass cover 130 so that light input from the outside may not reach the bonding wire 150. For example, the first width W1 of the second region of the light blocking film 140 may be greater than a length from the outermost end of the second region of the light blocking film 140 to a point vertically overlapping an innermost end of the third bonding pads 152 closest to the outermost end of the second region of the light blocking film 140. For example, the second region of the light blocking film 140 may vertically overlap all of the bonding wires 150, e.g., to prevent light from being incident on the bonding wires 150, thereby preventing reflection of light from the bonding wires 150.

One end of each of the bonding wires 150 is bonded to a corresponding one of a plurality of second bonding pads 151 of the substrate 110, and the other end of the bonding wire 150 is bonded with a corresponding one of a plurality of third bonding pads 152 of the image sensor chip 120. The bonding wires 150 electrically couple the second bonding pads 151 of the substrate 110 and the third bonding pads 152 of the image sensor chip 120. In an embodiment, the bonding wires 150 may include or be formed of gold (Au), aluminum (Al), and/or copper (Cu).

FIG. 3 shows a cross-sectional view of an image sensor package 100 including a disposition of a metal portion 131 according to an embodiment.

Referring to FIG. 3, the metal portion 131 may be formed in the insulation layer 114 of the substrate 110. In an embodiment, lateral sides and a bottom surface of the metal portion 131 may be embedded in (e.g., contact) the insulation layer 114, and an upper surface of the metal portion 131 may be exposed from the insulation layer 114. In an embodiment, the upper surface of the metal portion 131 may have the same level as the upper surface of the insulation layer 114. For example, the upper surface of the metal portion 131 and the upper surface of the insulation layer 114 may be coplanar.

In an embodiment, part of the lateral side and the bottom surface of the metal portion 131 are embedded in (e.g., contact) the insulation layer 114, and other part of the lateral side and the upper surface of the metal portion 131 may be exposed from the insulation layer 114. In an embodiment, the upper surface of the metal portion 131 may protrude from the upper surface of the insulation layer 114. For example, the upper surface of the metal portion 131 may be at a higher level than the upper surface of the insulation layer 114.

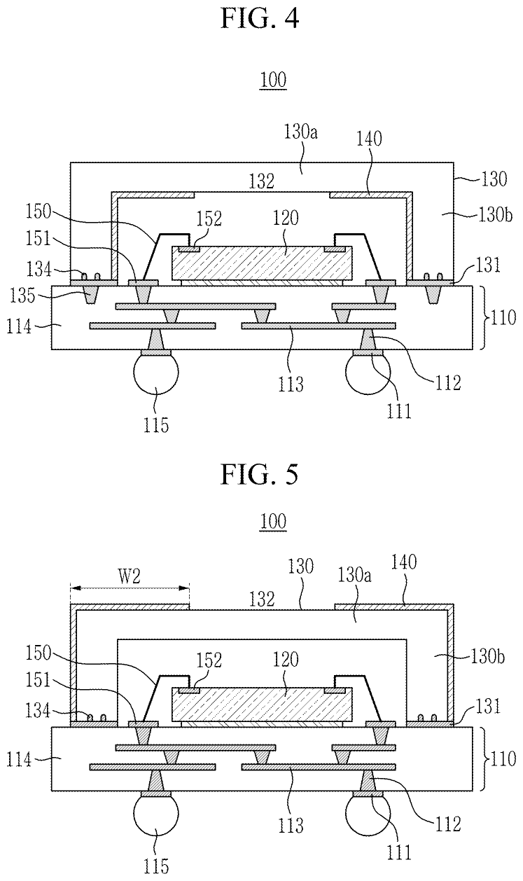

FIG. 4 shows a cross-sectional view of an image sensor package 100 including a disposition of a metal portion 131 according to an embodiment.

Referring to FIG. 4, the metal portion 131 may further include a fixing portion 135 at the bottom surface. An upper surface of the fixing portion 135 is bonded to the bottom surface of the metal portion 131, and lateral sides and a bottom surface of the fixing portion 135 are embedded in (e.g., contact) the insulation layer 114 of the substrate 110. The fixing portion 135 is bonded to the metal portion 131 and firmly fixes the metal portion 131 to the substrate 110. In an embodiment, the fixing portion 135 may include or be formed of stainless steel (SUS), copper (Cu), and/or aluminum (Al).

The fixing portion 135 may be simultaneously provided/formed in a process for forming a plurality of redistribution vias 112, e.g., at an uppermost portion/layer of the substrate 110. In an embodiment, the metal portion 131 may include/have a square ring shape surrounding lateral sides of the image sensor chip 120, and the fixing portion 135 may include/have the same shape as the shapes of the redistribution vias 112 at the uppermost portion/layer. Therefore, the fixing portion 135 may have a similar shape to or the same shape as a plurality of redistribution vias and be disposed at regular intervals on the bottom surface of the square ring shape of the metal portion 131. In an embodiment, the fixing portion 135 includes/has a similar shape to or the same shape as the redistribution vias, and may be electrically insulated from the image sensor chip 120 and the redistribution lines 113 of the substrate 110.

FIG. 5 shows a cross-sectional view of an image sensor package 100 including a disposition of a light blocking film 140 according to an embodiment.

Referring to FIG. 5, the light blocking film 140 may include a first region extending along the external surface of the sidewalls 130b of the transparent glass cover 130 and a second region extending in a direction approaching a center of an inner surface of the upper plate from the edge of the external surface of the upper plate 130a of the transparent glass cover 130. For example, the first region of the light blocking film 140 may be formed on the whole outer surface of the sidewalls 130b of the transparent glass cover 130. For example, the edge of the external surface of the upper plate 130a meets/contacts a top end of the external surface of the sidewalls 130b of the transparent glass cover 130. For example, a top end of the first region meets/contacts an edge of the second region of the light blocking film 140. The second region of the light blocking 20) film 140 may have a predetermined second width W2. In an embodiment, the predetermined second width W2 of the second region of the light blocking film 140 may be longer than a length up to a crossing of a vertical direction of the location on which the bonding wire 150 is bonded to a plurality of third bonding pads 152 on the image sensor chip 120 and the external surface of the upper plate 130a of the transparent glass cover 130 from the edge of the external surface of the upper plate 130a of the transparent glass cover 130 so that light input from the outside may not reach the bonding wire 150. For example, the second width W2 of the second region of the light blocking film 140 may be greater than a length from the outermost end of the second region of the light blocking film 140 to a point vertically overlapping an end point (e.g., an innermost point) of the third bonding pads 152 closest to the outermost end of the second region of the light blocking film 140. For example, the second region of the light blocking film 140 may vertically overlap all of the bonding wires 150, e.g., to prevent light from being incident on the bonding wires 150, thereby preventing reflection of light from the bonding wires 150.

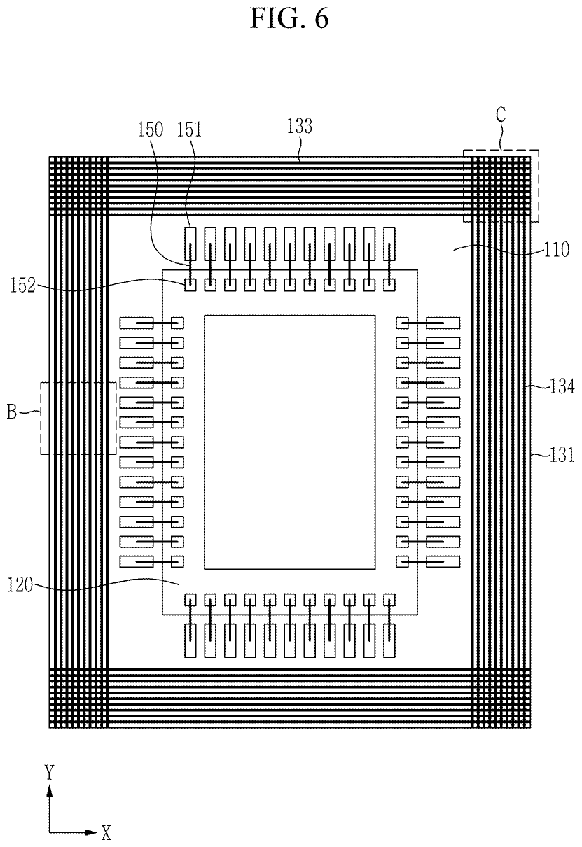

FIG. 6 shows a top plan view of an interface between a transparent glass cover 130 and a metal portion 131 of a substrate 110 according to an embodiment. The transparent glass cover 130 and the metal portion 131 of the substrate 110 may be directly bonded to each other.

Referring to FIG. 6, an interface between the transparent glass cover 130 and the metal portion 131 includes laser welding lines 133 to which the transparent glass cover 130 and the metal portion 131 of the substrate 110 are bonded to each other.

The interface between the transparent glass cover 130 and the metal portion 131 may include X-direction laser welding lines 133 extending lengthwise in an X-direction and Y-direction laser welding lines 134 extending lengthwise in a Y-direction to which the metal portion 131 and the transparent glass cover 130 are bonded. In an embodiment, the X-direction laser welding lines 133 may be formed on the X-direction metal portion 131, the Y-direction laser welding lines 134 may be formed on the Y-direction metal portion 131, and the X-direction laser welding lines 133 and the Y-direction laser welding lines 134 may traverse/cross each other on the metal portion 131 at a corner of the image sensor package 100. In an embodiment, each of the X-direction laser welding lines 133 and the Y-direction laser welding lines 134 including portions crossing each other may be formed on at least one of: the X-direction metal portion 131, the Y-direction metal portion 131, and the metal portion 131 at the corner. For example, the X-direction laser welding lines 133 and the X-direction metal portion may extend lengthwise in an X-direction, and the Y-direction laser welding lines 134 and the Y-direction metal portion may extend lengthwise in a Y-direction.

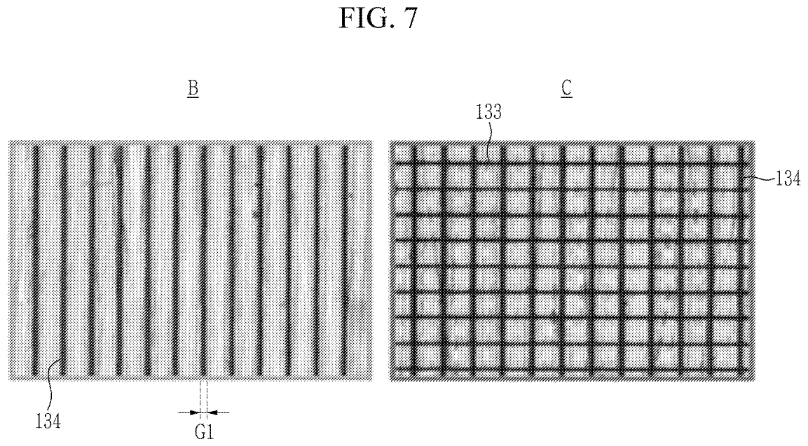

FIG. 7 shows an image of regions B and C in a top plan view on an interface between a directly bonded transparent glass cover 130 and a metal portion 131 of a substrate 110 of FIG. 6 according to an embodiment.

Referring to FIG. 7, a region B may include the Y-direction laser welding lines 134, and a region C may include the X-direction laser welding lines 133 and the Y-direction laser welding lines 134 that traverse each other. The X-direction laser welding lines 133 and the Y-direction laser welding lines 134 may have a width G1 of 3 um to 50 um, respectively. For example, the width of the X-direction laser welding lines 133 in the Y-direction and the width of the Y-direction laser welding lines 134 in the X-direction may be the same.

When the laser welding is performed such that the laser welding lines in two directions traverse each other, the transparent glass cover 130 and the metal portion 131 are firmly fixed and the image sensor package 100 may be further sealed, compared to the case of performing laser welding providing one-direction laser welding lines. For example, the two direction (X-direction and Y-direction) laser welding lines may be beneficial to the sealing and to firm fix between the transparent glass cover 130 and the metal portion 131. However, when the laser welding is performed to provide one-direction laser welding lines, a processing time is reduced by an amount of the performance, which is a merit. For example, choosing a design having the one-direction (X-direction or Y-direction) leaser welding lines may be beneficial to reducing the processing time.

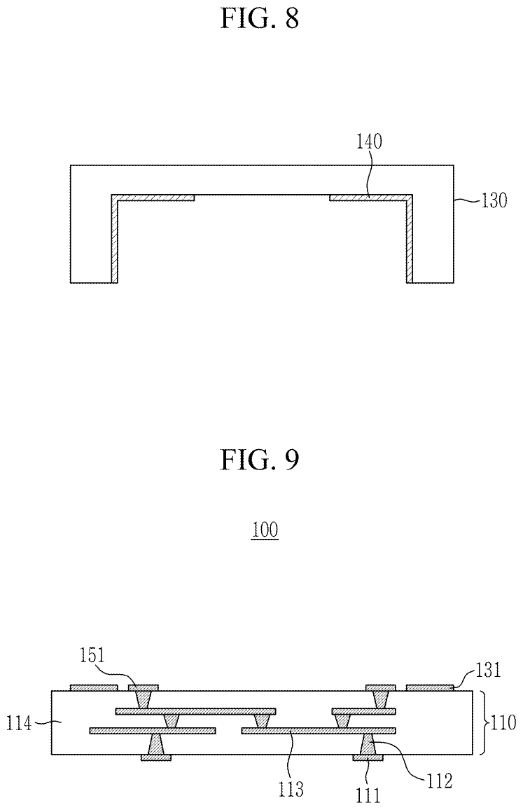

FIG. 8 shows a cross-sectional view of providing a transparent glass cover 130 in a method for manufacturing an image sensor package 100 according to an embodiment.

Referring to FIG. 8, the transparent glass cover 130 is manufactured from a transparent glass substrate (not shown). A photoresist deposition, a photomask layer deposition, an exposure, a development, and an etching process are performed on the transparent glass substrate to provide a cavity in the transparent glass substrate and manufacture the transparent glass cover 130. The transparent glass cover 130 includes or be formed of an upper plate 130a and sidewalls 130b defined by a lower cavity.

An ink composition is printed on the transparent glass cover 130 to generate the light blocking film 140. In an embodiment, the ink composition may include tricobalt tetroxide, magnetite black, copper·iron·manganese black, and/or titan black with a starting raw material such as carbon black, a copper·iron·manganese complex oxide, or a cobalt oxide. In another embodiment, the light blocking film 140 may be made by attaching a light blocking film (e.g., a ready-made light blocking film) to the transparent glass cover 130.

The light blocking film 140 may be provided to include a first region extending along the surface of the sidewalls 130b of the transparent glass cover 130 and a second region extending in a direction approaching a center of an inner surface of an upper plate 130a of the transparent glass cover 130 from the edge of the surface of the upper plate 130a of the transparent glass cover 130. The first region of the light blocking film 140 may be provided on the sidewalls 130b of the transparent glass cover 130. The second region of the light blocking film 140 may be provided so that the light input from the outside may not reach the bonding wire 150. For example, the second region of the light blocking film 140 may vertically overlap the whole of the bonding wire 150.

FIG. 9 shows a cross-sectional view of providing a substrate 110 in a method for manufacturing an image sensor package 100 according to an embodiment.

Referring to FIG. 9, a plurality of redistribution vias 112 are provided on the lowermost portion/layer in a process for forming a substrate 110. The redistribution vias 112 may be provided by a photoresist etching process or a hard mask etching process. In an embodiment, the redistribution vias 112 may include or be formed of at least one of: copper, aluminum, tungsten, nickel, gold, tin, titanium, and their alloys. In an embodiment, the redistribution vias 112 may be made by performing a sputtering process. In another embodiment, the redistribution vias 112 may be made by generating a seed metal layer and then, performing an electroplating process.

After the redistribution vias 112 are provided, the insulation layer 114 is provided at the height of the same level as the upper surface of the redistribution vias 112. In an embodiment, the insulation layer 114 may include or be formed of a molding compound, a molding underfill, an epoxy, and/or a resin. In an embodiment, the insulation layer 114 may be deposited by a chemical vapor deposition (CVD), an atomic layer deposition (ALD), a plasma-enhanced chemical vapor deposition (PECVD), or another method.

Then, the redistribution vias 112 and the upper surface of the insulation layer 114 are planarized by applying a CMP process or a mechanical grinding process.

Then, in the process for providing a substrate 110, a plurality of redistribution lines 113 are provided in the redistribution vias 112 disposed at the lowest portion/layer. Characteristics of the above-described process for providing a plurality of redistribution vias 112 may be identically applied to the process for providing the redistribution lines 113, and layers of the redistribution vias 112 and the redistribution lines 113 may be repeatedly provided.

Then, in the process for providing a substrate 110, a metal portion 131 is provided on the insulation layer 114. In an embodiment, the metal portion 131 may include a square ring shape in a plan view. In an embodiment, the metal portion 131 may be provided by performing a sputtering process. In another embodiment, the metal portion 131 may be provided by generating a seed metal layer and then, performing an electroplating process. In an embodiment, the metal portion 131 may include or be formed of stainless steel (SUS), copper (Cu), and/or aluminum (AI). The metal portion 131 may be electrically insulated from the image sensor chip 120 and the redistribution lines 113 of the substrate 110.

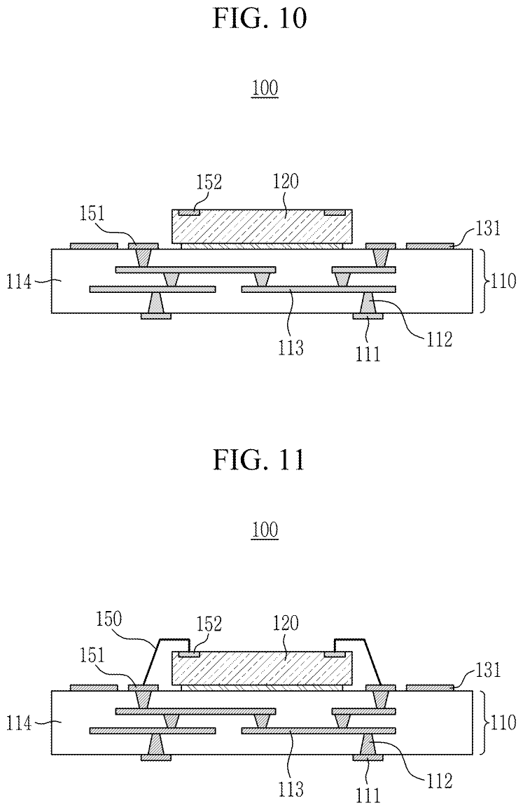

FIG. 10 shows a cross-sectional view of mounting an image sensor chip 120 on a substrate 110 in a method for manufacturing an image sensor package 100 according to an embodiment.

Referring to FIG. 10, the image sensor chip 120 is mounted on the substrate 110. An adhesive is applied between the bottom surface of the image sensor chip 120 and the upper surface of the substrate 110, and the image sensor chip 120 may be bonded to the substrate 110. In an embodiment, the image sensor chip 120 may include or may be a CMOS image sensor.

FIG. 11 shows a cross-sectional view of electrically coupling an image sensor chip 120 and a substrate 110 by use of a bonding wire 150 in a method for manufacturing an image sensor package 100 according to an embodiment.

Referring to FIG. 11, the image sensor chip 120 mounted on the substrate 110 is electrically coupled to the redistribution lines 113 included in the substrate 110 by the bonding wire 150.

One end of each of bonding wires 150 is bonded to a corresponding one of the second bonding pads 151 of the substrate 110, and the other end of the bonding wire 150 is bonded to a corresponding one of third bonding pads 152 of the image sensor chip 120. The bonding wires 150 electrically couples the second bonding pads 151 and the third bonding pads 152 of the image sensor chip 120. In an embodiment, the bonding wires 150 may include or be formed of gold (Au), aluminum (Al), and copper (Cu).

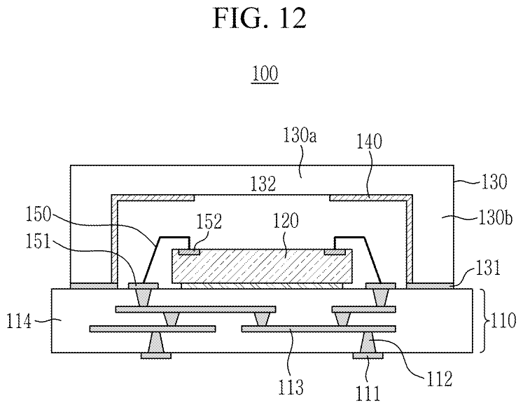

FIG. 12 shows a cross-sectional view of disposing a transparent glass cover 130 on a substrate 110 in a method for manufacturing an image sensor package 100 according to an embodiment.

Referring to FIG. 12, as a previous stage/step performed before performing laser welding the transparent glass cover 130 and the metal portion 131, the upper surface of the metal portion 131 of the substrate 110 and the bottom surface of the transparent glass cover 130 are cleaned with a detergent and are arranged. The detergent may include anhydrous ethanol. After the upper surface of the metal portion 131 of the substrate 110 and the bottom surface of the transparent glass cover 130 are arranged, the upper plate 130a of the transparent glass cover 130 is spaced from the upper surface of the image sensor chip 120, and the sidewalls 130b of the transparent glass cover 130 are spaced from the lateral sides of the image sensor chip 120. The light blocking film 140 provided on the transparent glass cover 130 is disposed at the location on which it may prevent the light input coming from the outside from being reflected by the bonding wire 150 and being input to the image sensor.

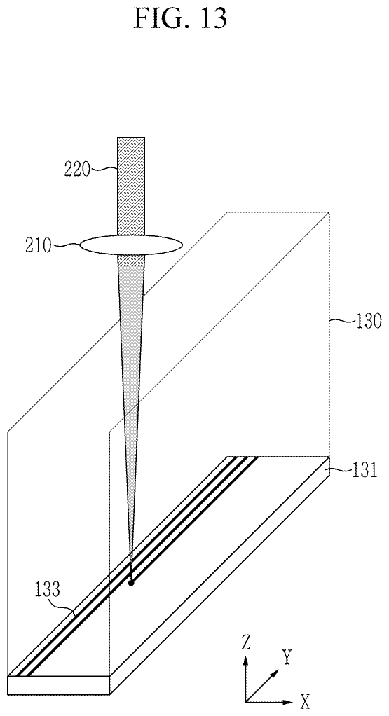

FIG. 13 shows bonding a metal portion 131 of a substrate 110 and a transparent glass cover 130 by laser welding in a method for manufacturing an image sensor package 100 according to an embodiment.

Referring to FIG. 13, the metal portion 131 and the transparent glass cover 130 are bonded by performing a laser welding, and the laser welding lines 133 and 134 are provided on the interface between the metal portion 131 of the substrate 110 and the transparent glass cover 130. Laser beams 220 may be focused on a region (a focus region) at the interface between the metal portion 131 and the transparent glass cover 130 by the lens 210.

When laser beams 220 are radiated, in the focus region, the metal portion 131 consecutively undergoes an expansion, a melting, and a phase transformation, a liquefied metal of the metal portion 131 moves to the transparent glass cover 130 and is coagulated, the coagulated metal fills a gap between the transparent glass cover 130 and the metal portion 131 so the metal portion 131 and the transparent glass cover 130 are bonded to each other, and the laser welding lines 133 and 134 are provided/formed. The laser welding lines 133 and 134 protrude toward the transparent glass cover 130 from the metal portion 131. In an embodiment, each of the laser welding lines 133 and 134 may have a width G1 of 3 um to 50 um.

The laser beams 220 may include femtosecond laser beams. The femtosecond laser beams have a pulse width of 10⁻¹⁵. In an embodiment, the laser beams 220 may include a pulse duration of 100 ns to 400 fs. In an embodiment, the laser beams 220 may have a wavelength of 355 nm to 1064 nm.

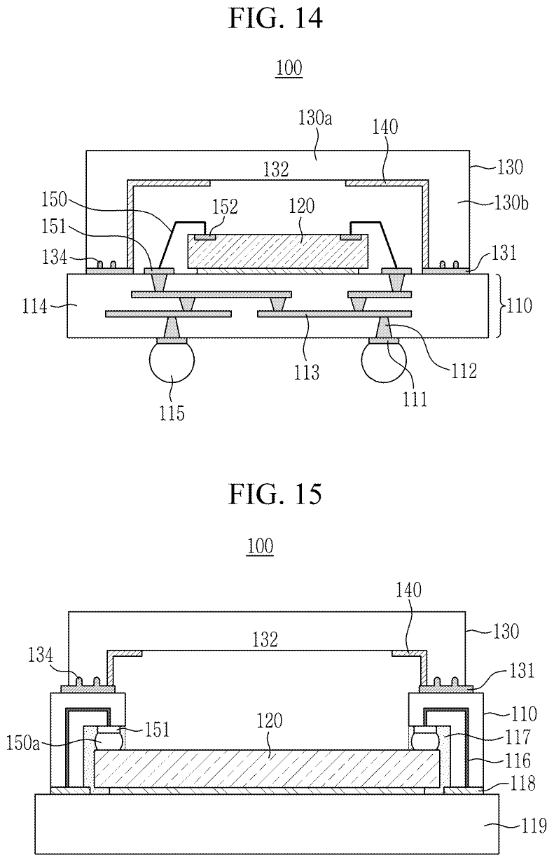

FIG. 14 shows a cross-sectional view of an image sensor package 100 after a laser welding step, in which a transparent glass cover 130 which has an integrated structure and a metal portion 131 of a substrate 110 seal/encapsulate an image sensor chip 120 according to an embodiment.

Referring to FIG. 14, the transparent glass cover 130 and the metal portion 131 are bonded to each other by the laser welding, and the image sensor chip 120 is sealed/encapsulated by the transparent glass cover 130 and the substrate 110. For example, the transparent glass cover 130 and the substrate 110 may airtightly enclose the image sensor chip 120 within a cavity formed between the transparent glass cover 130 and the substrate 110.

FIG. 15 shows a cross-sectional view of an image sensor package 100 for sealing/encapsulating an image sensor chip 120 mounted on a substrate 110 by a flip chip bonding method with a transparent glass cover 130 having an integrated structure and a metal portion 131 of a substrate 110 according to an embodiment.

Referring to FIG. 15, the image sensor chip 120 may be bonded onto the substrate 110 not by a wire bonding method but by a flip chip bonding method. The image sensor chip 120 bonded onto the substrate 110 by the flip chip bonding method may be sealed/encapsulated by the transparent glass cover 130, the substrate 110, and the lower printed circuit board (PCB) 119. The transparent glass cover 130 and the metal portion 131 of the substrate 110 are bonded by a laser welding.

The image sensor chip 120 bonded onto the substrate 110 by the flip chip bonding method may be bonded to the second bonding pads 151 on the substrate 110 and may be electrically coupled to the substrate 110 by a connection member 150a at the 10) upper portion of the image sensor chip 120. In embodiment, the substrate 110 may include or may be a printed circuit board (PCB) made of a ceramic material. The substrate 110 may include a metal trace 116. In embodiment, the connection member 150a may include or may be a bump of Au made by an Au—Au bonding. A peripheral portion of the connection member 150a and a space between the image sensor chip 120 and the substrate 110 may be filled by the underfill 117.

The image sensor chip 120 may be mounted on the lower printed circuit board (PCB) 119. Fourth bonding pads 118 of the lower printed circuit board (PCB) 119 may be electrically coupled to the metal trace 116 of the substrate 110.

Contents disclosed as an embodiment given with FIG. 1 to FIG. 14 may be applied to the image sensor chip 120 according to the flip chip bonding method of FIG. 15, and various types of semiconductor packages in addition to the wire bonding and the flip chip bonding are included in the range of the present disclosure.

According to the present disclosure, the image sensor chip 120 is sealed by the transparent glass cover 130 and the metal portion 131 of the substrate 110 without the support holder and the resin. The hermeticity (e.g., airtightness) may be tested with a method checking whether helium (He) gas permeates into a cavity enclosing an image sensor chip of an image sensor package when the cavity is in a vacuum state and the image sensor package is disposed in a helium gas with certain pressure, and the image sensor chip 120 according to the present disclosure has excellent hermeticity. Hermeticity is beneficial to protecting image sensor chips, e.g., from moisture or harmful gases.

Therefore, according to the present disclosure, the issues that may be generated when the image sensor chip is sealed with multiple materials having different thermal expansion coefficients may be addressed by sealing the image sensor chip 120 with reduced components/materials, e.g., two components or two types of materials, no bonding material may be used, and the process may be simplified.

Further, according to the present disclosure, issues such as the high temperature aqueous vapor pressure risk and the possibility of generating cracks by use of the resin may be addressed, high heat resistance and high rigidity may be obtained, and high-level results may be obtained in the thermal cycle test (TC).

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context indicates otherwise.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An image sensor package comprising:
a substrate including a metal portion;
an image sensor chip on the substrate; and
a transparent glass cover disposed on the substrate and including an upper plate and sidewalls, the upper plate and the sidewalls defined by a cavity at a lower portion and spaced from the image sensor chip,
wherein the sidewalls are directly bonded to the metal portion of the substrate, and
the image sensor chip is sealed by the transparent glass cover and the substrate.

2. The image sensor package of claim 1, further comprising
a light blocking film consecutively extending along surfaces of the sidewalls and along an edge of a surface of the upper plate.

3. The image sensor package of claim 1, wherein
the upper plate and the sidewalls are integrated.

4. The image sensor package of claim 1, wherein
the metal portion includes a square ring shape surrounding the image sensor chip.

5. The image sensor package of claim 1, wherein
the metal portion includes stainless steel (SUS), copper (Cu), or aluminum (AI).

6. An image sensor package comprising:
a substrate including an insulation layer, redistribution lines and redistribution vias formed in the insulation layer, and a metal portion;
an image sensor chip on the substrate;
a connection member for electrically coupling the redistribution lines and the image sensor chip;
a transparent glass cover disposed on the substrate and including an upper plate and sidewalls, the upper plate and the sidewalls defined by a cavity at a lower portion and spaced from the image sensor chip;
a light blocking film consecutively extending along surfaces of the sidewalls and along an edge of a surface of the upper plate; and
laser welding lines protruding from the metal portion,
wherein the sidewalls are directly bonded to the metal portion by the laser welding lines, and
the image sensor chip is sealed by the transparent glass cover and the substrate.

7. The image sensor package of claim 6, wherein
the metal portion is electrically insulated from the image sensor chip and the redistribution lines.

8. The image sensor package of claim 6, wherein
an upper surface of the metal portion protrudes from an upper surface of the insulation layer.

9. The image sensor package of claim 6, wherein
an upper surface of the metal portion has a same level as the upper surface of the insulation layer.

10. The image sensor package of claim 6, wherein
the image sensor package includes a fixing portion bonded to a bottom surface of the metal portion and embedded in the insulation layer.

11. The image sensor package of claim 6, wherein
the connection member includes a bonding wire.

12. The image sensor package of claim 11, wherein
the light blocking film includes
a first region extending along an internal surface of the sidewalls, and
a second region having a predetermined first width and extending toward a center of an internal surface of the upper plate from an edge of the internal surface of the upper plate.

13. The image sensor package of claim 12, wherein
the predetermined first width is longer than a length from the edge of the internal surface of the upper plate to a point of the surface of the upper plate vertically overlapping an end point of a bonding pad to which the bonding wire is bonded.

14. A method for manufacturing an image sensor package comprising:
forming a substrate including an insulation layer, redistribution lines and redistribution vias formed in the insulation layer, and a metal portion;
mounting an image sensor chip on the substrate; and
directly bonding a transparent glass cover onto the metal portion by laser welding to seal the image sensor chip.

15. The method of claim 14, wherein
in the directly bonding of a transparent glass cover onto the metal portion, laser welding lines in a first direction bonding the metal portion and the transparent glass cover to each other are formed on the metal portion.

16. The method of claim 15, wherein
in the directly bonding of a transparent glass cover onto the metal portion, laser welding lines in a second direction bonding the metal portion and the transparent glass cover to each other are formed on the metal portion, and
the second direction traverses the first direction.

17. The method of claim 14, wherein
in the laser welding, the laser has a pulse duration of 100 ns to 400 fs.

18. The method of claim 14, wherein
in the laser welding, the laser has a wavelength of 355 nm to 1064 nm.

19. The method of claim 14, further comprising
forming a transparent glass cover in which a cavity is formed by an etching, before the directly bonding of a transparent glass cover on the metal portion by laser welding to seal the image sensor chip.

20. The method of claim 19, further comprising
printing ink on the transparent glass cover.
